(19) United States
(12) Patent Application Publication
(10) Pub. No.: US 2012/0196051 A1
(43) Pub. Date: Aug. 2, 2012

(54) Deposition Apparatus and Methods

(75) Inventors: Anatoly Kuzmichev, Kiev (UA); Igor V. Belousov, Kyiv's Region (UA); Yuriy G. Kononenko, Kyiv (UA); John F. Mullooly, Oklahoma City, OK (US)

(73) Assignee: UNITED TECHNOLOGIES CORPORATION, Hartford, CT (US)

(21) Appl. No.: 13/016,223

(22) Filed: Jan. 28, 2011

(51) Int. Cl. C23C 16/513; C23C 16/50; C23C 14/30; C23C 16/48

(52) U.S. Cl. 427/570; 118/723 EB; 118/708; 118/696

(57) ABSTRACT

A deposition apparatus includes a deposition chamber and a deposition material source. An electron beam source is positioned to direct a first electron beam to vaporize a portion of the deposition material. A first electrode is provided for generating a primary plasma from the deposition material source. A second electrode is provided for generating a secondary plasma and further accelerating ions from the primary plasma. A bias electric potential is applied to the workpiece to draw ions from the secondary plasma to the workpiece. A control system may be coupled to the electron beam source, the bias voltage source, and power supplies for the first and second electrodes.

### BACKGROUND

The disclosure relates to deposition of coatings via ion-enhanced electron beam physical vapor deposition (IE-EBPVD). More particularly, the disclosure relates to deposition of aerospace coatings including dimensional restorative coatings.

The components of gas turbine engines are subject to wear and damage. Even moderate wear and damage of certain components may interfere with optimal operation of the engine. Particular areas of concern involve the airfoils of various blades and vanes. Wear and damage may interfere with their aerodynamic efficiency, produce dynamic force imbalances, and even structurally compromise the worn/damaged parts in more extreme cases. Various techniques have been proposed for restoration of worn or damaged parts of gas turbine engines. U.S. Pat. No. 7,509,734 (US '734) to Memmen et al. (the disclosure of which is incorporated by reference in its entirety herein as if set forth at length) discloses an ion enhanced electron beam physical vapor deposition (IE-EBPVD) system. As is discussed further below, that system or a similar system may serve as the baseline for modification according to the principles herein.

Additionally, IE-EBPVD has been proposed for use in non-restorative aerospace coatings. One example is found in U.S. Pat. No. 4,109,061 which discloses deposition of a MCrAlY-type (where M is Ni and/or Co) coating such as is used as a bondcoat for a thermal barrier coating (TBC) system.

As is discussed further below, coating processes, including IE-EBPVD, have suffered various problems/limitations which present themselves as competing considerations. For example, in general, a broad deposition footprint, a high deposition rate, and a high quality of deposition may be desirable. However, these may compete adversely with each other. Particularly, attempts at achieving high deposition rate are associated with coating defects including spitting. Spitting is generally associated with liquid droplets impacting the substrate/workpiece and causing microstructural discontinuities. It is believed that high electron beam power causes microbursts of vapor at the melt pool. The microbursts tend to eject liquid which forms spits.

### SUMMARY

One aspect of the disclosure involves an apparatus for depositing material on a workpiece. The apparatus includes a deposition chamber and a deposition material source. An electron beam source is positioned to direct a first electron beam to vaporize a portion of the deposition material. First means is provided for generating a primary plasma from the deposition material source. Second means is provided for generating a secondary plasma and further accelerating electron from the primary plasma. There may be means for applying a bias electric potential to the workpiece to draw ions from the secondary plasma to the workpiece. A control system may be coupled to the electron beam source, the means for generating a primary plasma, the means for generating a secondary plasma, and the means for applying a bias potential.

In various implementations, the first means may comprise a first anode. The first anode may fully encircle a flowpath from the deposition material source to the workpiece. The first means may comprise a circular ring. The second means may comprise one or more electrodes. The deposition material may comprise an MCrAlY or a Ti-based alloy (more narrowly, may consist essentially of or consist of such MCrAlY or Ti-based alloy).

The details of one or more embodiments are set forth in the accompanying drawings and the description below. Other features, objects, and advantages will be apparent from the description and drawings, and from the claims.

### BRIEF DESCRIPTION OF THE DRAWINGS

FIG. 1 is a partially schematic view of a first ion-enhanced physical vapor deposition apparatus.

FIG. 2 is a transverse schematic view of the positional relationships between an anode of a second deposition apparatus and a substrate/workpiece.

FIG. 3 is a schematic transverse view of the positional relationships between anodes of a third deposition apparatus and a substrate.

Like reference numbers and designations in the various drawings indicate like elements.

### DETAILED DESCRIPTION

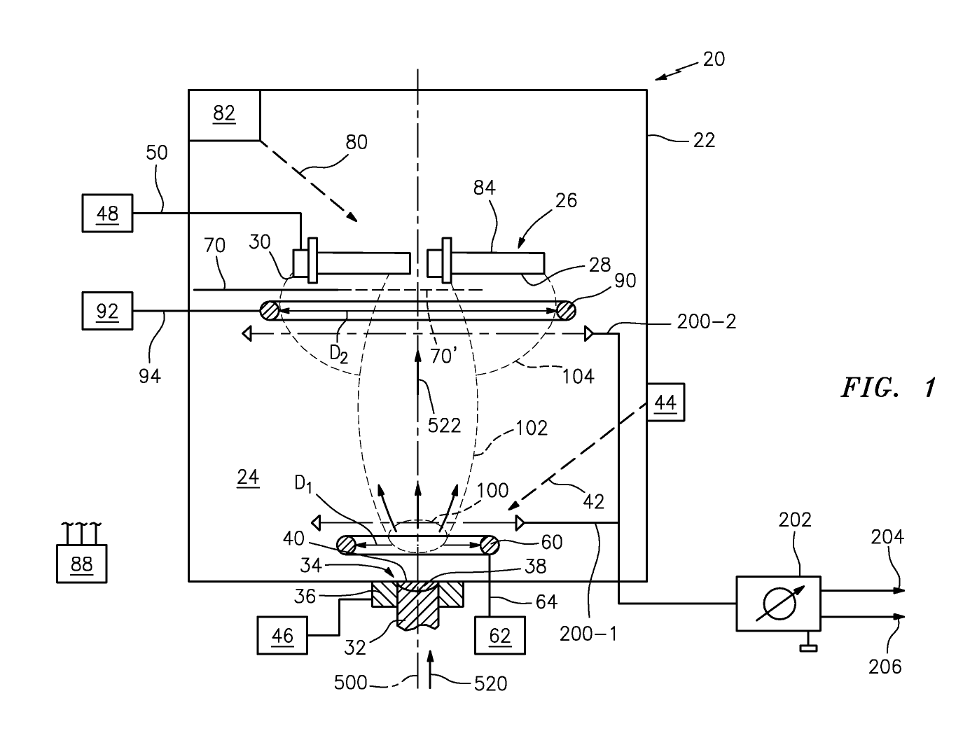

FIG. 1 shows an ion-enhanced EBPVD (IE-EBPVD) apparatus 20 for performing the foregoing deposition. The apparatus includes a vacuum chamber 22 having an interior 24. A workpiece 26 (e.g., a turbine engine part) having a surface portion 28 for receiving deposition is positioned in the chamber interior and held by a fixture 30. The chamber may have various additional features (not shown) such as an integral vacuum pump for pumping down the chamber, a load lock chamber and a sting/actuator for introducing and removing the workpiece 26, and various sensors.

The exemplary dimensional restoration deposition (e.g., of a damaged/worn turbine engine blade or other workpiece) is performed at a pressure between 10⁻¹ and 10⁻⁴ Pa, more narrowly, approximately (5-10)×10⁻³ Pa. The exemplary deposition rates are between 10 and 100 micrometers per minute, more narrowly, between 10 and 50 micrometers per minute, with an exemplary approximately 20 micrometers per minute. The localized deposition may build up to essentially any depth in one or more stages. In an exemplary dimensional restoration situation, the separate stages may be characterized by some combination of intervening machining or repositioning of the component relative to the vapor source. Individual stages may well deposit material to depths over 2 mm, over 5 mm, or even more.

The deposition material may, at least in part, come from an ingot 32 which may be progressively and continuously inserted into the chamber 22 along an axis 500 in insertion direction 520 through a chamber port 34. Exemplary ingot material is chosen to achieve a desired chemistry for the resulting deposited material. For example, it may be desirable that the deposited material has the same chemistry as the basic substrate material of the workpiece being repaired. Where the latter is a pure elemental material, the former may be likewise. With alloys, however, there may need to be chemistry variations for several reasons. The reasons may vary depending upon the chemistry of the alloy, the structure of the deposition apparatus, and the operational parameters of the deposition apparatus. For example, the lightest vaporized alloy elements (e.g., aluminum in a titanium-aluminum-vanadium alloy and vapor mixture) may be forced toward the periphery of the vapor stream by the heavier elements (e.g., the titanium). To the extent that the workpiece is aligned with the center of the stream, the deposited material will tentatively reduce concentrations of lighter elements relative to their original concentration in the ingot. Accordingly, to achieve a desired deposition material composition, the ingot may have a higher concentration of lighter elements. Thus, to deposit an exemplary Ti-6Al-4V material, a Ti-8Al-4V ingot may be utilized. Alternative mechanisms may cause depletion of specific components. These may include failure of the components to reach the workpiece and may also include ejection of components from deposited coating during deposition.

Appropriate seals (not shown) may be provided to prevent leakage around the ingot. Alternatively, the ingot and its progressive movement actuator (not shown) may be located within the chamber 24. An inboard end of the ingot becomes positioned within a crucible 36 along a bottom one of the walls defining the chamber. A molten pool (melt pool) 38 of metal from the ingot is formed within the chamber and has a surface or meniscus 40. The ingot is melted to provide the pool via an electron beam 42 emitted from an electron gun 44 which may be positioned within or without the chamber to direct the beam to the inboard ingot end/pool. The crucible serves to contain the pool. The crucible is advantageously cooled to keep it from melting (e.g., by passing a cooling fluid such as water through an external cooling jacket (not shown)). In the exemplary embodiment, the crucible is an electromagnetic crucible unit having a cylindrical winding around the ingot powered by a power supply 46. The energized winding generates a magnetic field within and above the molten pool 38. Exemplary magnetic field inductions are 0.003-0.06 T. The magnetic field serves to help focus the electron beam 42, which may have been defocused by the ionizing discharge plasma and the magnetic field of the discharge current, so as to enhance the evaporation rate. The magnetic field also helps stabilize the ionizing discharge on the surface 40 by preventing the movement of discharge cathode spots to a crucible periphery and, thereby, avoiding vacuum arc burning on the crucible body. The magnetic field helps control the discharge plasma parameters by affecting the ionization degree and spatial distribution. The magnetic field also influences rotational flow of metal in the pool 38. This flow helps enhance mixing of the components of the molten metal and decreases metal spitting. The rotation of liquid metal is a result of the interaction of electrical current in the metal, caused by the electron beam and ionizing discharge, with the magnetic field of the winding. The rotation also enhances evaporation efficiency due to decreased heat transfer to the cooled crucible wall.

The heating by the electron beam is effective to vaporize the metal in the pool. To draw positively charged metal ions from the vapor to surface 28, the workpiece 26 is subjected to a negative bias. A pulse modulator 48 is coupled to the workpiece 26 via a line/conductor 50. The bias voltage may have a square pulse wave form characterized by a pulse repetition frequency F_{b} (pulse rate), a pulse width τ_{b}, duty cycle D_{b}, and a peak voltage U_{b}. D_{b}=τ_{b}×F_{b}. Alternate bias voltage wave forms may be used (e.g., sinusoidal). With a non-modulated direct current bias, arc discharge (arcing) would likely occur on the surface 28, especially in the first few seconds of deposition. Such discharge may damage the surface. Pulse modulation of the bias voltage may effectively suppress such arcing. Decreasing of pulse width decreases the probability of arcing as arc formation needs sufficient time (e.g., from one hundred to several thousands of microseconds). Even if an arc discharge occurs, the break (pause) between bias pulses would quickly interrupt the discharge.

Bias voltage parameters may vary greatly based upon the nature of the apparatus, the nature of the deposition material, the size of the workpiece (mass and linear dimensions), and the like. The exemplary peak voltage is a negative voltage in the range of 50-10,000 V. The exemplary pulse repetition frequency is in the range of 0.05-150 kHz. The exemplary pulse width is ≧about 5 μsec. Such pulse width may be selected because only a few of the ions would reach the workpiece with full energy if there were shorter pulses of like voltage. Ions generated from vapor species of metal atoms need a relatively long time (roughly proportional to their mass) to pass across the space charge shell around the workpiece to reach the workpiece from the vapor plasma. The shell separates the vapor plasma from the workpiece with negative potential. The metal ions are accelerated by the bias voltage. The time needed for the ions to cross the shell (e.g., about 1 μs) would practically need to be shorter than the pulse width τ_{b}. The bias voltage parameters may be changed dynamically during the deposition process to control parameters of deposition, especially the temperature of the workpiece. The process may begin with relatively high U_{b} and D_{b} with the value then decreasing to keep the workpiece temperature within a target range. The values may be increased if the temperature reaches or falls below the low end of such range. In an exemplary implementation, only the duty cycle is varied during operation. For example, during initial interval of an exemplary 0.5-2.0 minutes the duty cycle may be approximately 0.9. The duty cycle is then decreased to a value of approximately 0.1-0.4 for several minutes to avoid overheating. The duty cycle may incrementally be increased back toward the 0.9 value as appropriate to maintain the operating temperature within the target range. The pulse modulator 48 (FIG. 1) may include a modulation electronic tube as in US '734. The electronic tube (e.g., a triode, tetrode, or the like) serves as a fast switch device periodically connecting the primary DC power source of negative polarity (not shown in FIG. 1) to the workpiece 28 and thereby generating the negative bias voltage pulses. The primary DC power source voltage can be regulated to determine the peak value of the bias voltage. The pulse modulator may also contain a generator (not shown) of control pulses applied to the control grid of the electronic tube. The control pulse parameters determine the parameters of the bias voltage pulses (F_{b}, τ_{b}, D_{b}, U_{b}). Current and voltage probes (not shown) may be coupled to the electronic tube and provide outputs which may be monitored as via an oscilloscope (not shown) or other electronic means (e.g., a special-purpose computer). Such monitoring may serve to verify normal operation of the pulse modulator. Alternative voltage modulators may be used to generate the bias voltage (e.g., based on thyratrons, thyristors, transistors, and step-up transformers). However, electronic tube modulators may provide a desired combination of robustness and control of current delivered to the workpiece to limit sparking and arcing. An aspect of exemplary electronic tube modulators is that the tube anode current is determined mainly by voltages of the control grid (and by the screen grid in tetrodes and pentodes) and weakly by the anode voltage. Therefore, in the case of arcing on the workpiece the tube anode voltage may sharply rise and become equal to the primary anode DC power source voltage while the control grid voltage remains the same. Accordingly, the anode current (that is the workpiece current) will be practically the same as without arcing. Thus, the anode current may slightly increase and this slightly increased current is the maximum current to the work piece during arcing. Thus, the electron tube acts to automatically limit the load current. Alternative modulation devices may have difficulty limiting current in the load circuit and may therefore need a very fast acting safeguard system for turning off current in the event of arcing on the workpiece surface.

To maintain an ionizing discharge along a vapor/ion flowpath 522 from the pool 38 to the surface 28, a first ionizing anode electrode 60 (e.g., a ring at least partially surrounding the path 522) is connected to a power supply 62 via a line/conductor 64. The discharge may provide the necessary degree of ionization of evaporated species. The degree of ionization may be characterized by an ion current density jᵢ on the deposition surface. Exemplary jᵢ are 1-50 mA/cm², more narrowly, approximately 2-10 mA/cm². This may be associated with an exemplary discharge current of 50-500 A and associated discharge voltage of 5-50V. For deposition of titanium alloys, an exemplary associated discharge voltage Uₐ₁ is 8-20V. A pulse modulator (not shown) may be provided between the power supply 62 and ring 60 to modulate the ionizing discharge. The ionizing discharge may have a pulse rate (pulse repetition frequency) Fₐ₁, a pulse width τₐ₁, a duty cycle Dₐ₁=τₐ₁×Fₐ₁, and a peak current Iₐ₁.

Modulation of the ionizing discharge may have several effects. Decreasing the duty cycle shortens discharge on-time which is associated with the period during which the discharge affects (e.g., defocuses) the electron beam 42. Such defocusing may decrease the evaporation rate. The modulation may stabilize the ionizing discharge by preventing jumping of a discharge from the surface of the pool to the crucible body periphery to prevent vacuum arc burning on the crucible body. Such burning is quite disadvantageous because the crucible material may provide undesirable impurities in the deposited materials. The main mechanism of vacuum arc excitation on the conductive surface of the crucible body is the electrical explosion of sharp microscopic irregularities due to their heating by the field emission current (e.g., for which the plasma of the ionizing discharge serves as an anode). Sufficient heating requires a sufficient interval. The pulsing of the ionizing discharge provides periodic interruption of the heating of and field emission from the crucible microscopic irregularities to permit sufficient cooling to ensure a stable discharge. The modulation parameters are chosen to provide a desired current density on the deposition surface of the workpiece with desired ionizing discharge stability in view of permissible effects upon the electron bean and evaporation rate. Exemplary modulation parameters involve a frequency Fₐ₁ in the range of 1-10,000 Hz, more narrowly 100-1,000 Hz, and a duty cycle Dₐ₁ in the vicinity of 0.5-0.99, more narrowly 0.8-0.99. One or more discharge pulse parameters may be varied during deposition process. For example, duty cycle may be gradually decreased during some period after the beginning of the deposition process. A decrease to zero might provide a soft transition from ion-enhanced EBPVD to conventional EBPVD. Various wave forms may be used alternatively to the square pulse.

A shutter 70 may have a first position (solid line) clear of the flowpath 522 and a second position (broken line) 70′ blocking the flowpath 522. The shutter may be positioned downstream of the anode ring 60 along the flowpath 522. The shutter may be in the second position 70′ during preparation as the apparatus is brought up to initial target operating conditions. During this stage, the ingot material is melted to form the pool, the ionizing discharge is established, the negative bias voltage is applied to the workpiece, and the workpiece may be preheated. The workpiece 26 may be preheated via an electron beam 80 delivered by a second electron gun 82 to impact a non deposition surface portion 84 of the workpiece. The preheating may serve to clean the deposition surface by pyrolysis and desorption of surface impurities. This may enhance binding and adhesion of deposited material and avoid thermal shock during the initial stages of deposition. In an exemplary embodiment, the preheating may be varied to provide a gradual increase in workpiece temperature effective to achieve a desired rate of vapor, thermo-desorbed from the workpiece, in view of equipment parameters limiting the evacuation of such vapor while avoiding unacceptable oxidation of the workpiece. Preheating parameters may depend greatly upon the geometry and mass of the workpiece. The exemplary preheating brings the workpiece to a temperature no greater than the maximum operational target temperature, and, more particularly, generally within the operational target temperature range. With the parameters in the initial target range, the shutter is opened to expose the workpiece to deposition. During deposition, the workpiece may be heated by the second electron gun 82, by the ion bombardment, by heat radiation (e.g., from the melted metal in the pool), and by the latent heat of the atoms condensing in the deposition. The second electron gun is turned off if the temperature exceeds the maximum of an operational target range and may be turned off so long as the temperature is within the target range. It may, however, be switched back on if the temperature falls below a minimum of the target range. For example, if the deposition rate is decreased toward the end of a deposition process, the electron gun may need to be turned back on during the decreased rate stage.

Operation may be controlled by a control system (controller) 88 which may receive user inputs from input devices (not shown, e.g., switches, keyboard, or the like) and sensors (not shown). The controller may be coupled to the controllable system components (e.g., pumps, valves, power supplies, EB guns, actuators, and the like) via control lines (e.g., hardwired or wireless communication paths). The controller may include one or more: processors; memory (e.g., for storing program information for execution by the processor to perform the operational methods and for storing data used or generated by the program(s)); and hardware interface devices (e.g., ports) for interfacing with input/output devices and other system components.

The foregoing description of a single-anode system may represent a baseline system from which the present system is formed as a reengineering/remanufacturing. Whereas the first anode 60 is relatively upstream along the flowpath 522, a second anode 90 is added relatively downstream. The second anode 90 is coupled to the positive pole of a power source 92 via a conductor 94 to apply a positive bias voltage Uₐ₂ to the second anode. The exemplary second anode 90 is, more narrowly, positioned in a last third of an axial distance between the pool surface 40 and the substrate deposition surface 28, yet more narrowly, a last tenth. This may be contrasted with the position of the first anode 60 well upstream (e.g., in the upstream third but, more particularly, at an absolute axial distance of 1-10 cm, more narrowly, 2-3 cm from the pool surface).

In operation, the first anode 60 encourages formation of an initial arc discharge plasma 100. This plasma diffuses with the flow in a pattern 102 extending toward/to the substrate surface 28. With the single-anode system, ion current density distribution has a pronounced maximum just above the crucible. This leads to non-uniform conditions (to non-uniform ion enhancing and, as consequence, non-uniform coating properties) over the coating surface of a large substrate. Increasing the crucible-to-substrate distance may make more uniform the ion current density distribution but it leads to decreasing the deposition rate and ion current density value. Increasing evaporating electron beam power to overcome the low deposition rate at larger crucible-to-substrate distances causes, as noted above, splashing of melted metal in a crucible and spit deposition. Additionally, mean energy of electrons in the plasma of pattern 102 substantially decreases with axial distance from the initial arc discharge plasma 100 mainly due to collisions with vapor specimens. Therefore, vapor ionization may be limited/insignificant above the first anode. This effectively limits the ion current to the substrate because increasing arc discharge current to the first anode may provoke cathode arcs at the crucible body periphery. Thus, there is a trade-off between high-rate spit-free deposition and high-rate large surface coating deposition.

The second anode 90 provides additional ionization and generates a spreading secondary plasma 104 in a wide space between the crucible and the substrate close to the deposition surface 28. This is done by creating an electrical field that accelerates electrons from the freely diffusing plasma 102 and increases their mean energy to the level of effective vapor ionization. As is discussed below, this may have the effect of increasing overall deposition rate but, more significantly, may be used to increase uniformity of deposition (especially over relatively broad areas). With a relatively small ratio of jᵢ (e.g., 1-50 mA/cm²) to deposition rates (e.g., 10-100 micrometers per minute) the deposition rates are defined mainly by evaporation rate (EB power) and not by ion bombardment. Ions are needed only for ion modification/enhancing of the deposited coatings (enhancing microstructure/density, adhesion, etc.) The non-uniform ion bombardment causes non-uniform properties of coatings. As is discussed below, also a spreading secondary plasma encourages relatively for spit-free deposition; via droplet elimination in large space between the crucible and the substrate.

The exemplary second anode 90 is a ring. The exemplary ring has an internal diameter D₂ which may be contrasted with an internal diameter D₁ of the first anode. The effect of the second anode 90 is stronger near its surface. Thus, the additional vapor ionization it provides is greater radially near the second anode 90 than near the axis 500 (or other center of the flowpath). This may have the effect of evening out (broadening/flattening) the transverse distribution of total ion current density and temperature and coating deposition distribution. The broadening/flattening of jᵢ does not directly affect coating thickness distribution; it affects the coating deposition conditions, including distribution of ion enhancing of coatings and elimination of spit/splash deposition on the broad substrate area. The more broad and more dense secondary plasma 104 (relative to diffusion plasma 102) ensures plasma evaporation of droplets/splashes on the flowpath from crucible to substrate. Thus, regulation of the operation of the second anode 90 may be used to provide a desired deposition condition uniformity. This may, for example, be achieved by measuring relative temperatures near the center and near the periphery and, increasing second anode voltage and/or duty cycle to increase relative peripheral temperature if desired (and vice versa). This may also be achieved by measuring secondary plasma density using plasma probes near the center and near the periphery of the substrate holder, or by measuring deposition rates with suitable sensors.

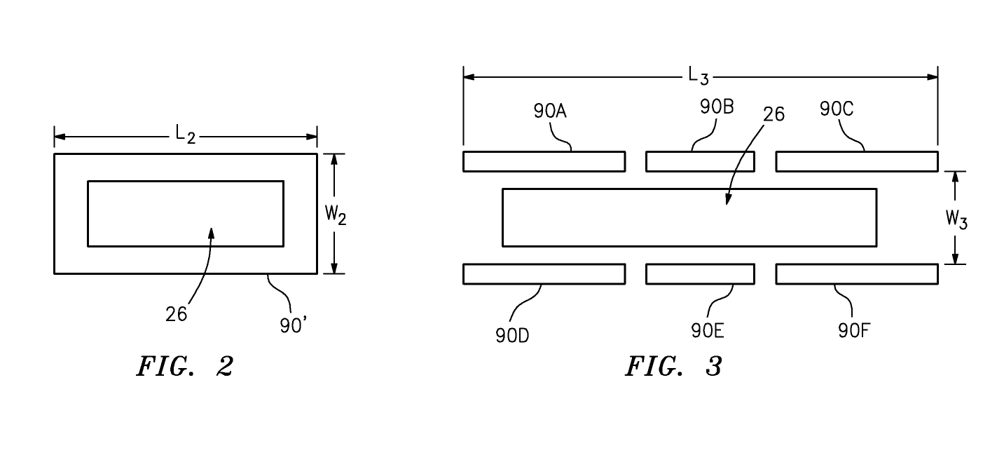

Because of the relationship between the second anode and the transverse coating distribution, it may be desirable to configure the second anode to correspond to the planform shape of the substrate being coated (or the group of substrates being coated). For example, FIG. 2 shows a plan view of an elongate (e.g., rectangular) substrate 26 and an alternate second anode 90′. However, this may alternatively represent the elongate (e.g., rectangular) planform outline of an array of smaller substrates being coated as a group. The characteristic transverse dimension D₂ is replaced by width and length W₂ and L₂. One can provide a desired deposition condition uniformity by modification of the second anode shape (e.g., via experimentation/optimization). The measurement of suitable parameters (e.g., secondary plasma density, near the center and near the periphery of the substrate holder) may be used for monitoring of the deposition condition uniformity.

In yet another alternative embodiment (FIG. 3), the second anode is represented by a group of second anodes which, in transverse projection, partially surround the perimeter of the substrate. To provide the individual anodes with water cooling, they may each be made from separate copper pipes and may have the shape of closed (or nearly closed) narrow rectangular rings so that the cooling water can flow around each ring. These may be powered in common (e.g., at the same voltage as each other by a single power supply) or may be individually powered by associated power supplies or may be powered in groups. The combination of powering may be chosen in view of the needs of uniformity. The measurement of suitable parameters (e.g., secondary plasma density, near the center and near the periphery of the substrate holder) may be used for monitoring of the deposition condition uniformity. The exemplary transverse dimensions of the space between these anodes are shown as W₃ and L₃.

Construction-wise, the exemplary second anode 90 may be formed as: one or more simple metal ring(s) (e.g., from copper pipe) or vertical metal plate(s); a vertically oriented spiral (coil-shaped); a circular ring with vertical zig-zag; or like a hamster wheel (with end rings joined by a circumferential array of links). The shape of this anode may be configured to provide effective generation of a large (extended) uniform secondary plasma. The second anode may be water-cooled or non-cooled. This may be distinguished from the first anode which may be of more simple shape, for example like a circular or rectangular metal ring or as a vertical metal plate(s). The first anode supports arc discharge on the liquid metal pool in the crucible and prevents arcing on the crucible body surface. The first anode may be water-cooled or non-cooled.

Exemplary process parameters may vary based upon the substrate material, deposition material, substrate geometry, and apparatus capacities. In an exemplary process, the first anode may be operated at a relatively low voltage magnitude (e.g., 5-20V to avoid cathode arc-type discharge on the crucible periphery and vapor). An exemplary inner diameter D₁ of the first anode is 100-300% of the crucible outer diameter, more narrowly, 150-200%.

The first anode operational regime was discussed above. Exemplary Dₐ₁ is in the vicinity of 0.5-0.99, more narrowly 0.8-0.99. This regime may be different from the first anode regime of US '734 to support the first plasma with minimal pause. This helps with arcing prevention and effective droplet plasma self-evaporation. The voltage and other parameters may be similar to those of US '734. The second anode operational regime is discussed below.

Whereas the size of the first anode is coupled to crucible/ingot parameters in view of the relatively low radial diffusion of vapor at that location, the transverse dimensions of the interior of a ring-like second anode or a space between a ring of second anodes is more tied to the planform of the workpiece or array of workpieces. These dimensions will likely be substantially greater than the transverse linear dimension (e.g., a diameter) of the first anodes. For example, exemplary transverse linear internal dimensions of the second anode (or array) are 150-200% (more broadly, 120-250%) of the aligned/adjacent transverse linear dimension of the substrate (or substrate array/group). Said transverse linear internal dimension of the second anode (or array) (D₂ and one or both of L₂ or W₂ (or one of both of L₃ and W₃)) may well be 200-1000% of a characteristic transverse linear internal dimension (D₁) of the first anode.

The second anode(s) may be powered by direct current power/voltage Uₐ₂. An exemplary magnitude of voltage Uₐ₂ is in the range of 100-5000V, more narrowly, 100-1000V. Depending on circumstances, this may be an exemplary 10-1000 times the first anode voltage Uₐ₁. The second anode ionizing discharge may be also powered by pulsed direct current power and have a pulse rate (pulse repetition frequency) Fₐ₂, a pulse width τₐ₂, a duty cycle Dₐ₂=τₐ₂×Fₐ₂, and a peak current Iₐ₂.

The sensed parameters include those related to: the electron beams for evaporation and substrate heating (currents, voltages, parameters of beam scanning); ingot evaporation rate (may be measured defined by ingot feeding rate into the crucible; these parameters are proportional to each other) and/or deposition rate (the evaporation rate parameter gives information on deposition rate because these parameters are proportional to each other; primary arc discharge for vapor ionization, more specifically to the first anode regime (average or peak current Ia₁, duty cycle Dₐ₁ or pulse width Lₐ₁, and a peak voltage Uₐ₁; Fₐ₁ (pulse rate) may be constant or Dₐ₁ may be equal to 1 in the non-modulated operation mode); secondary plasma, more specifically to the second anode regime (average or peak current Iₐ₂, duty cycle Dₐ₂ or pulse width τₐ₂, and a peak voltage Uₐ₂; Fₐ₂ (pulse rate) may be constant or Dₐ₂ may be equal to 1 in the non-modulated operation mode); negative substrate bias (duty cycle D_{b} or pulse width τ_{b}, and a peak voltage U_{b}, F_{b} (pulse rate) may be constant); substrate ion current (this current is close to the total current in the substrate circuit because the secondary electron emission current of the substrate surface under ion bombardment is much less than the substrate ion current; the total current is sum of bombarding ion and electron emission currents); and substrate temperature (it may be useful to measure temperature in different points when the substrate is of complex shape). For plasma monitoring, one or several plasma probes (probe array) may be used. The probe(s) may be located near the first anode and/or near the substrate at one or several points (the latter case is for monitoring of uniformity of deposition conditions). The output signals of the sensors go to the computer system for monitoring and control of deposition process parameters. Most of the parameters may be kept constant during deposition process but some of them (mainly duty cycle D_{b} or EB current for substrate heating) may be varied during deposition accordingly the deposition process procedure and feedback signals to provide a desired temperature regime of the substrate.

Various general techniques and specific methods of electrical and temperature measurements and different types of sensors/measuring devices (well known in electro-engineering, electronics, pulse techniques, plasma physics/techniques, thermophysics, etc.) employed for deposition processes monitoring may be used. The density of the primary and second plasmas (100 and 104) of the first and second ionizing discharges, accordingly, may be monitored by a plasma probe or probe array 200-1, 200-2 (FIG. 1) within the chamber 24 and connected to a registration system 202 which may have output ports 204, 206 to permit monitoring (e.g., via either ammeter/voltmeter or an oscilloscope, or computer-based measuring digital device (which may be the control system 88 or a portion thereof)). An exemplary probe may be an electrode under negative potential relative to the plasma in order to measure the saturated ion current. By surrounding the path 522 with one or more arrays of probes, the spatial non uniformity of the ionizing discharges may be monitored. A plasma probe (or probe array 200-1) located in the vicinity of the first anode will monitor the first ionizing (initial) discharge (first plasma 100). A plasma probe (or probe array 200-2) located in the vicinity of the second anode will monitor the second ionizing discharge (secondary plasma 104). Spatial non-uniformity of plasmas may be caused by asymmetric heating of the pool by the electron beam and asymmetrical distribution of the first ionizing discharge over the pool, asymmetrical spatial distribution of the vapor stream, and by asymmetrical ionization from the secondary anode. The probes may be used for monitoring the spatial distribution of the vapor stream as well. The probes may be used both in ion enhanced EBPVD and conventional EBPVD to the extent that the evaporating electron beam 42 would provide some ionization of the vapor effective to generate current in the probe circuits. The current may be a proportion of the vapor density and evaporation rate. With pulse modulation of the ionizing discharge, probe current during the pulses may be used for discharge monitoring. Probe current between discharge pulses may be used for evaporation monitoring. The monitoring may allow quick detection of defects in the process and may provide for its stabilization via a feedback loop. For example, it is possible to stabilize the evaporation rate by control of the electron beam 42 so as to maintain constant probe current between pulses.

A pulse mode of second anode operation may be useful for prevention of arcing on substrate(s) and deposition chamber parts. Exemplary modulation parameters involve a frequency Fₐ₂ in the range of 0.05-150 kHz, more narrowly 0.5-10 kHz, and a duty cycle Dₐ₂ in the vicinity of 0.5-0.99, more narrowly 0.8-0.99. Various waveforms may be used alternatively to the square pulse. If pulse repetition frequencies Fₐ₁, Fₐₜ and F_{b} are equal or at least divisable each to other, the pulses (Uₐ₁, Uₐ₂, U_{b}) with such frequencies may be synchronized as this may enhance prevention of arcing on the substrate and chamber wall surfaces. For instance, if F_{b}=Fₐ₂, then we have the same (synchronized) pauses in powering the substrate bias circuit and the second anode (second ionization discharge) that ensures total discontinue of the powering of a parasitic arc on the substrate and chamber wall surfaces (if such arcs have arisen) and favorable in break off of the arcing. If arcing has not arisen during the pulse, one may consider the probability of the arcing. Arcing is provoked when there are: 1) sufficient (high) plasma/ion density near a negatively biased surface (that ≡ plasma density or ˜ to current Iₐ₂ of the second ionization discharge and is proportional to plasma density or current Iₐ₁ of the first ionization discharge); and 2) sufficient (high) voltage between the plasma and the surface (the voltage between the plasma and the substrate surface is sum of Uₐ₂+U_{b}; the voltage between the plasma and the chamber wall surface is Uₐ₂). Thus, synchronized pauses in powering the substrate bias circuit (when U_{b}→0) and the second anode (second ionization discharge) circuit (when Uₐ₂→0, Iₐ₂→0) may be used to prevent arcing. The second anode(s) may be also powered by radio (high) frequency (0.1-100 MHz) or microwave (superhigh) frequency (e.g., 2.45 GHz) power. Such power supply may provide higher level of vapor ionization in conditions of low vapor pressure together with prevention of arcing.

Operation of the dual-anode system may be used to achieve spit reduction in deposited metal coatings such as are used in turbine element manufacture and repair (e.g., an MCrAlY used as a bondcoat for a thermal barrier coating (TBC) system or Ti-based material used for body repair of Ti-based turbine elements). This is relieved due to enhanced plasma self-evaporation of small droplets ejected from the melt pool via the splash effect.

For example, the ejected droplets have very high temperature (e.g., on the order of 2000 C for the MCrAlY or Ti-based alloy). During droplet flight, they continue to evaporate. The primary and additional plasmas provided by the first and second anodes are believed to further heat the droplets to raise their temperature and cause further evaporation. The thermo-electron emission from the droplet surface with high temperature promotes collection of high energy plasma species (plasma electrons with high energy) due to the favorable effect of the emission on the droplet potential within the plasma. Intensive thermo-electron emission from the droplet surface leads to vanishing of droplet negative floating potential (moving it to positive side). In so doing, the intensity of its bombarding by plasma electrons (energy flux from plasma onto the droplet) is rapidly increased. This is accompanied by a rapid increase of droplet material evaporation rate. Ionization of metal vapor by plasma electrons near the droplet surface leads to formation of a vapor-plasma cloudlet around the droplet. Getting the energy from the surrounding discharge plasma, the droplet surface can effectively evaporate during droplet motion through plasma toward complete evaporation of the droplet. The second anode generates and heats the secondary plasma (it heats mainly plasma electrons). So, the longer the droplet path in plasma, the more enhanced the droplet evaporation is.

The broadening of the plasma provided by the second anode may allow yet further changes relative to a baseline system. For example, for the baseline system, the distance between the melt pool and the workpiece may be dictated by the desire to have a given transverse dimension of the vapor plume to provide a given deposition footprint. This imposes a minimum value for the separation. By effectively broadening the deposition footprint, this may allow for a reduction in the pool-to-workpiece separation. This separation reduction may allow a more compact deposition chamber and may increase deposition rates relative to deposition at a longer separation.

One or more embodiments have been described. Nevertheless, it will be understood that various modifications may be made. For example, although particularly useful with blades, the methods may be applied to other turbine parts and non-turbine parts. Details of the particular turbine engine part or other piece and the particular use and chemistry of the deposition material influence details of any given deposition. When implemented in the remanufacturing of an existing system or the reengineering of an existing system configuration, details of the existing system or configuration may influence details of any particular implementation. Accordingly, other embodiments are within the scope of the following claims.

What is claimed is:

1. An apparatus for depositing material on a workpiece comprising:
a deposition chamber;
a deposition material source;
an electron beam source, positioned to direct a first electron beam to vaporize a portion of the deposition material;
first means for generating a primary plasma from said deposition material source;
second means for generating a secondary plasma and further accelerating electrons from the primary plasma;
means for applying a bias electric potential to the workpiece to draw ions from the secondary plasma to the workpiece; and
a control system coupled to the electron beam source, the means for generating a primary plasma, the means for generating a secondary plasma, and the means for applying a bias potential.

2. The apparatus of claim 1 wherein:
the control system is programmed to, in at least one mode:
operate the first means at a first positive potential; and
operate the second means at a second positive potential at least 1000% of the first positive potential.

3. The apparatus of claim 1 wherein:
the control system is programmed to:
monitor:
density of at least one of the primary plasma and secondary plasma; and
an ion current to the workpiece; and
provide feedback loop control of deposition of the material.

4. The apparatus of claim 1 wherein:
the first means is a first anode ring fully encircling a flowpath from the source to the substrate; and
the second means is a second anode ring fully encircling the flowpath downstream of the first anode ring.

5. An apparatus for depositing material on a workpiece comprising:
a deposition chamber;
deposition material at least partially within the deposition chamber;
a first electron beam source, positioned to direct a first electron beam to vaporize a portion of the deposition material;
a first ionizing electrode surrounding a flowpath from the deposition material;
a second ionizing electrode surrounding the flowpath downstream of the first electrode;
an ionizing voltage source coupled to the first ionizing electrode and second ionizing electrode to apply a first ionizing voltage to the first ionizing electrode and a second ionizing voltage to the second ionizing electrode;
a bias voltage source connected to apply an electric potential to the workpiece; and
a control apparatus coupled to the bias voltage source and the ionizing voltage source and configured to, in at least a first operational condition, apply said first and second ionizing voltages of like sign and different magnitude.

6. The apparatus or claim 5 wherein:
the first ionizing electrode comprises a circular ring; and
the second ionizing electrode is formed other than as a circular ring.

7. The apparatus or claim 6 wherein:
the second ionizing electrode is a non-circular ring.

8. The apparatus or claim 6 wherein:
the second ionizing electrode comprises a plurality of separately-powered electrodes.

9. The apparatus of claim 5 wherein:
the ionizing voltage source comprises:
a first power supply coupled to the first ionizing electrode; and
a second power supply coupled to the second ionizing electrode; and
the first operational condition is characterized by the magnitude of the second ionizing voltage being at least one order of magnitude higher than the magnitude of the first ionizing voltage.

10. The apparatus of claim 5 wherein a source of the deposition material source comprises a crucible and wherein:
a transverse linear internal dimension of the first ionizing electrode is 100-300% of the crucible outer diameter; and
a transverse linear internal dimension of the second ionizing electrode is 150-200% of a transverse linear dimension of the substrate and 200-1000% of a said transverse linear internal dimension of the first ionizing electrode.

11. The apparatus of claim 5 wherein:
the control apparatus is coupled to the first and second ionizing electrodes for pulse modulation of ionization.

12. The apparatus of claim 5 wherein:
the control apparatus is programmed to control the bias voltage source so as to prevent arcing from the workpiece.

13. The apparatus of claim 5 wherein:
the bias voltage source comprises an electronic tube acting to limit current to the workpiece.

14. The apparatus of claim 5 wherein:
the deposition material comprises an MCrAlY.

15. The apparatus of claim 5 wherein:
the deposition material comprises a Ti-based alloy.

16. A method for operating the apparatus of claim 5, the method comprising:
applying the first ionizing potential with:
a nominal voltage of 5V-50V;
a pulse repetition frequency of 1-10000 Hz;
a duty cycle of 0.8-0.99; and
applying the second ionizing potential with:
a nominal voltage of 100V-1000V;
a pulse repetition frequency of 0.05-150 kHz;
a duty cycle of 0.8-0.99.

17. The method of claim 16 comprising:
controlling the bias voltage source so as to apply the first potential with:
a nominal voltage of 50V-10 kV;
a pulse repetition frequency of 0.05-150 kHz;
a pulse width of at least 5 μs; and
a duty cycle of 0.1-0.99.

18. The method of claim 17 wherein:
the nominal voltage is 1-3 kV; and
the pulse repetition frequency is 0.5-10 kHz.

19. The method of claim 16 wherein:
the control apparatus is programmed to provide an ion current density of 1-50 mA/cm² at a deposition rate of 10-50 μm/minute.
the ion current density is 2-10 mA/cm² at a deposition rate of 15-20 μm/minute.
